(19) United States
(12) Patent Application Publication
(10) Pub. No.: US 2009/0258302 A1
(43) Pub. Date: Oct. 15, 2009

(54) SUB-RESOLUTION ASSIST FEATURE OF A PHOTOMASK

(75) Inventors: Jeng-Shiun Ho, Hsinchu (TW); Jun-Hua Chen, Yung-Ho City (TW); Luke Lo, Pingjhen City (TW); Louis Lin, Hsinchu City (TW); Bing-Syun Yeh, Hsinchu City (TW); Cheng-Cheng Kuo, Baoshan Township (TW); Hua-Tai Lin, Hsinchu (TW)

Correspondence Address: HAYNES AND BOONE, LLP;IP Section, 2323 Victory Avenue, Suite 700, Dallas, TX, 75219, US

(73) Assignee: TAIWAN SEMICONDUCTOR MANUFACTURING COMPANY, LTD., Hsin-Chu (TW)

(21) Appl. No.: 12/100,907

(22) Filed: Apr. 10, 2008

(51) Int. Cl. G03F 1/00; G06F 17/50

(52) U.S. Cl. 430/5; 716/11

(57) ABSTRACT

A photomask including a main feature, corresponding to an integrated circuit feature, and a sub-resolution assist feature (SRAF) is provided. A first imaginary line tangential with a first edge of the main feature and a second imaginary line tangential with the second edge of the main feature define an area adjacent the main feature. A center point of the SRAF lies within this area. The SRAF may be a symmetrical feature. In an embodiment, the center point of the SRAF lies on an imaginary line extending at approximately 45-degree angle from a corner of a main feature.

### BACKGROUND

In semiconductor fabrication, photomasks are used to define patterns that will be printed on a substrate such as a semiconductor wafer, during the photolithography process. However, variations in the intended pattern may be induced by optical interference and other effects. To prevent these effects, sub-resolution assist features are included on the photomasks as an application of resolution enhancement techniques (RET) and in particular, optical proximity correction (OPC). Assist features may increase the imaging resolution of a main feature (e.g., a feature to be imaged onto a substrate) with which they are associated.

Conventional resolution enhancement techniques include narrow lines of material placed adjacent and in line (e.g., parallel) a side of main feature. These features are typically known in the art, and described herein, as scattering bars. Scattering bars however may be difficult to place in highly dense patterns. Furthermore, scattering bars may provide inadequate off-axis illumination (OAI) performance in particular, while allowing a high numerical aperture (NA).

As such, an improved feature providing for resolution enhancement on a photomask is desired.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIG. 1 illustrates a top view of an embodiment of a layout of a main feature and an RET feature.

FIGS. 2, 3 and 4 illustrate top views of embodiments of layouts of a main features and a plurality of RET features.

FIGS. 5, 6, and 7 illustrate top views of configurations of a main feature and RET features as included in design file, photomask, and substrate respectively.

FIGS. 8, 9, and 10 illustrate top views of a plurality of embodiments of a main feature and associated RET features isolating the main feature.

FIGS. 11a, 11b, 12, 13, 14, and 15 illustrate top views of a plurality of embodiments of layouts including regular and uniform arrays of main features and associated RET features.

FIGS. 16, 17, 18, 19, 20, 21, and 22 illustrate tops views of a plurality of embodiments of layouts including a non-regular and uniform arrays of main features and associated RET features.

FIG. 23 illustrates a top view of a layout of an embodiment of non-regular and non-uniform configuration of main features and associated RET features.

FIGS. 24 and 25 illustrate graphs illustrating an embodiment of improvement of DOF using configurations including SRAFs oblique to a main feature.

FIG. 26 illustrates a flow chart of an embodiment of a method of providing RET.

FIGS. 27, 28, 29, 30, 31, and 32 illustrate embodiments of layouts including RET corresponding to the method of FIG. 26.

### DETAILED DESCRIPTION

The present disclosure relates generally to semiconductor devices, and more particularly, to a sub-resolution assistant feature (SRAF) provided on a photomask used in fabrication of semiconductor devices. It is understood, however, that specific embodiments are provided as examples to teach the broader inventive concept, and one of ordinary skill in the art can easily apply the teaching of the present disclosure to other methods or apparatus. For example, though described herein as providing a photomask for fabrication of semiconductor devices, any photolithography process may benefit from the disclosure, for example, glass substrate photomask used to form a thin film transistor liquid crystal display (TFT-LCD) substrate. In addition, it is understood that the methods and apparatus discussed in the present disclosure include some conventional structures and/or processes. Since these structures and processes are well known in the art, they will only be discussed in a general level of detail. Furthermore, reference numbers are repeated throughout the drawings for sake of convenience and example, and such repetition does not indicate any required combination of features or steps throughout the drawings.

The semiconductor fabrication process requires numerous photolithography steps in which an image (e.g., a pattern) formed on a photomask is projected onto a photosensitive film on a substrate (e.g., a semiconductor wafer). As pattern dimensions decrease, interference and processing effects that occur during the radiation of the image can negatively influence the pattern formed on the wafer. In other words, the pattern formed on the wafer may not be an accurate or adequate reproduction of the pattern designed and formed on the photomask. Resolution enhancement techniques (RET) including optical proximity correction (OPC) are used to more accurately reproduce the pattern. Such techniques may include providing RET features on the mask. RET features are sub-resolution features that will not be printed on the wafer, but are placed adjacent a feature that is to be imaged onto a wafer (e.g., a main feature) to improve its imaging. The SRAFs may allow a photolithography process to sharpen and more accurately reproduce the main feature and/or provide for a wider process window (e.g., allowed deviation in lithography parameters) used to image a main feature.

Conventional RET features have disadvantages, for example, with the use of scattering bars, it is difficult to provide a dense environment surrounding the main features in particular, when the main features are provided in a random layout (e.g., logic design). This lack of pattern density and uniformity is particularly acute in the regions provided between “corners” of features (e.g., in an oblique direction from a main feature).

Another conventional method of providing RET features includes assist features determined using a model-based methodology. This methodology may be able to provide an improvement in density of an environment, including providing a portion of an assist feature surrounding a main feature. However, numerous other disadvantages exist. For example, the complexity of the pattern (e.g. assist feature(s) shape) generated by the model provides difficulties in mask making, including increased mask fabrication cycle time and difficulties in printing the model-generated assist feature on a photomask. In addition, the procedures involved in determining the model-based assist features can, in itself, require a long cycle time (e.g., computing time). Furthermore, the model-generated assist features are typically very complex. This, as discussed above, provides difficult in mask fracturing. Further still, as the model-based methodology provides asymmetric and complex features, determining consistent results in wafer data can be difficult.

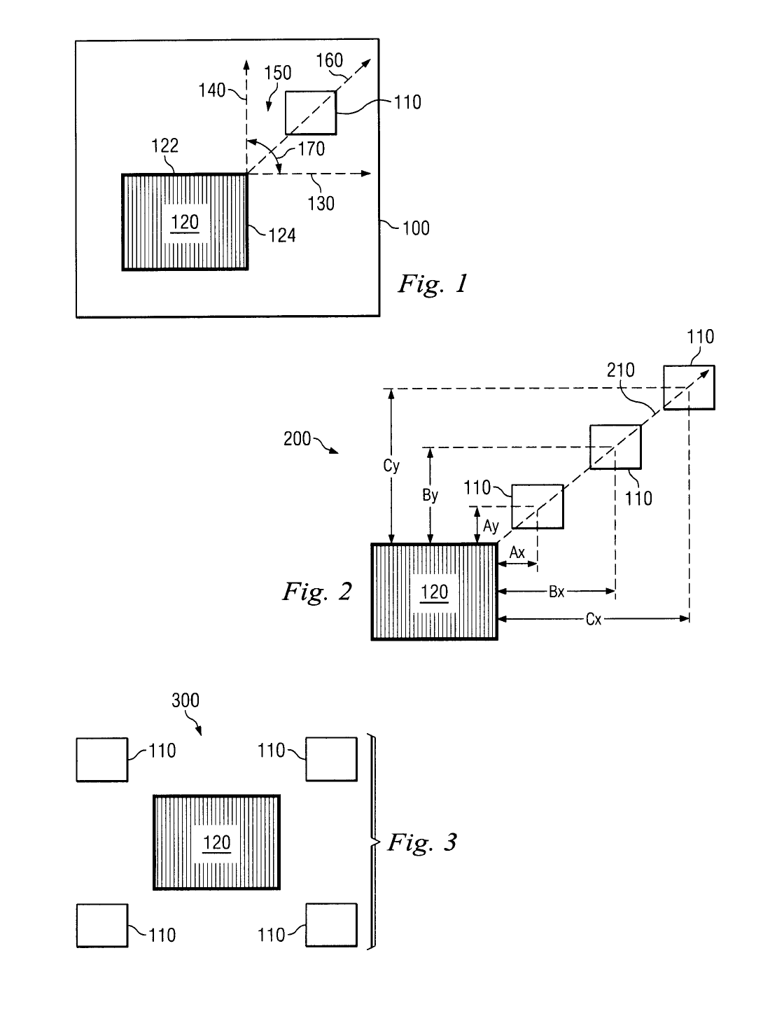

FIG. 1 illustrates an embodiment of a photomask 100 according to the present disclosure. The photomask 100 includes a sub-resolution assist feature (SRAF) 110 associated with a main feature 120. The SRAF 110 is described herein as an oblique SRAF, oblique describing its relative position in relation to the main feature 120, this is described in greater detail below.

The photomask 100 may be a binary mask, phase-shift mask including attenuated phase shift mask (attPSM), alternating phase shift masks (altPSM), chromeless phase lithography (CPL), and/or other photomask types known in the art. The photomask 100 includes a substrate. The substrate may be a transparent substrate such as fused silica (SiO₂), or quartz, relatively free of defects, calcium fluoride, or other suitable material. The main feature 120 may be designed to form a portion of an integrated circuit pattern on a semiconductor substrate, such as a wafer. The main feature 120 may be designed to form an integrated circuit feature such as a contact (e.g., via), an insulative region, a conductive line, a source and/or drain, a gate, a doped region, and/or other possible features. The main feature 120 may be formed of attenuating material disposed on the photomask. The attenuating material may include chrome or other materials such as, for example, Au, MoSi, CrN, Mo, Nb₂O₅, Ti, Ta, MoO₃, MoN, Cr₂O₃, TiN, ZrN, TiO₂, TaN, Ta₂O₅, NbN, Si₃N₄, ZrN, Al₂O₃N, Al₂O₃R, or a combination therefore. The main feature 120 may be formed using processes including photoresist deposition, soft baking, mask aligning, exposing (e.g., patterning), baking, developing the photoresist, hard baking, stripping the resist, and/or other processes. In alternative embodiments, the lithography patterning may include electron-beam writing, ion-beam writing, mask-less lithography, and/or molecular imprint. Though illustrated as a symmetrical and rectangular feature, the main feature 120 may be of any shape, size, or dimension. The main feature includes a first edge 122 and a second edge 124. In an embodiment, the first edge 122 includes the furthest point from a center point of the main feature 120 in the y-axis dimension (vertical), and the second edge 124 includes the furthest point from a center point on the main feature 120 in the x-axis dimension (horizontal). It should be noted that any reference to direction provided herein (e.g., vertical, horizontal) is used for ease of description and to provide relative relationship only and provides no limitation as to an absolute direction.

The SRAF 110 includes a dimension less than the resolution of the imaging system used with the mask. That is the SRAF 110 is of dimensions such that the feature will not image onto a semiconductor substrate (e.g., wafer) when the mask is irradiated. The SRAF 110 may be formed of attenuating material, be a phase shift feature (e.g., an etched portion of the photomask substrate), and/or any other feature type providing more efficient or effective imaging of the main feature 120. The SRAF 100 may include chrome or other materials such as, for example, Au, MoSi, CrN, Mo, Nb₂O₅, Ti, Ta, MoO₃, MoN, Cr₂O₃, TiN, ZrN, TiO₂, TaN, Ta₂O₅, NbN, Si₃N₄, ZrN, Al₂O₃N, Al₂O₃R, or a combination therefore. Though illustrated as symmetrical and rectangular, the SRAF 110 may include any variation of shape, size, and/or dimension. In an embodiment, the SRAF 110 is between approximately 0.4 and 0.9 times the minimum pattern size for a given geometry (e.g., the resolution limit of the fabrication process generation). In an embodiment, the SRAF 110 includes a rectangular shape including dimensions having a ratio between approximately ⅔ and 3/2. As described below with reference to FIG. 26, the shape of the SRAF 110 may be predetermined, e.g., generated before mask making processes. For example, the SRAF 110 may be determined to be symmetrical shape, for example, a rectangle. The shape, dimensions, size, and position of the SRAF 110 may be modified during the design and photomask making process. In an embodiment, the shape remains symmetrical.

The SRAF 110 includes a feature that is placed oblique (e.g., angled, diagonal) to the main feature 120. An oblique direction is illustrated by directional line 160 (illustrated for descriptive purposes only and not to imply any feature physically provided on the photomask 100). The illustrated line 160 is exemplary only and not intended to be limiting, for example, the line 160 may extend from the main feature and traverse any portion of an area 150, the area 150 described in further detail below. A line 130 (again illustrated for descriptive purposes only and not to imply any feature is physically provided on the photomask 100) is illustrated as extending from the side 122. In an embodiment, the line 130 is tangential to a point on the side 122. A line 140 (also illustrated for descriptive purposes only and not to imply any feature is physically provided on the photomask 100) is illustrated as extending from the side 124. In an embodiment, the line 140 is tangential to a point on the side 124. The lines 130 and 140 may be substantially perpendicular, that is, an angle range 170 may include approximately 90 degrees. The lines 130 and 140 define the area 150 adjacent the main feature 120. The area 150 includes the SRAF 110 or portion thereof. A center point (e.g., a point defining the geometric center of shape) of the SRAF 110 lies within the area 150. In an embodiment, the line 160 drawn within the bounds of the line 130 and 140 (e.g., within the angle range 170) traverses the center point of the SRAF 110. In an embodiment, though the line 130 and 140 define the angle range 170 of approximately 90 degrees to form the area 150, the center point of the SRAF 110 may be located within a portion the area 150 defined by a second angle range (a portion the angle range 170) of substantially less than 90 degrees (e.g., 60 degrees).

SRAF 110 is oblique to the main feature 120 in that it (e.g., a center point of the SRAF 110) lies on an imaginary diagonal line originating from a corner of the main feature and drawn away from the main feature, e.g., line 160. In an embodiment, the line 160 extends from a corner of the main feature 120 at an approximately 45-degree angle. In other words, the line 160 may dissect the angle range 170 and the area 150 in equal halves. In an embodiment, the SRAF 110 is oblique to the main feature 120 in that it lies on an imaginary diagonal line extending from the center point of the main feature 120 through a corner of the main feature 120, and away from the main feature 120, for example, at an approximately 45 degree angle to the corner. It should be noted that the main feature 120 is described herein a providing a corner. However, in embodiments, including the main feature 120 as formed on a photomask, a corner describes the mating of two edges of the main feature and does not necessitate such edges form a point, or a 90-degree angle. The mating of two edges may be defined by the lines 130 and 140.

The SRAF 110 is located a distance from the main feature 120. The distance includes a component in the direction of line 130 and a component in the direction of line 140. Though illustrated herein as approximately equal distances in both directions (e.g., the line 160 being at approximately 45 degrees), various other embodiments are possible. In an embodiment, the distance is between approximately 0.9 and 2.1 times the resolution limit of the fabrication process generation.

FIG. 1 provides an embodiment of a SRAF location according to the present disclosure, however, photomask 100 is illustrative only and not intended to be limiting in any manner. For example, in other embodiments, including those described herein, a portion of the SRAF 110 may lie outside of the area 150, a plurality of SRAFs may be included on the photomask 100 including a plurality associated with a single main feature 120, a plurality of SRAFs 110 may be within the area 150, and/or other possible configurations. Furthermore, though described herein as being provided on the photomask 100, the main feature 120 and the SRAF 110 described are equally illustrative of features and configurations (e.g., layouts) developed in the design of a device, for example, a design of an integrated circuit. For example, the configuration may be represented by data used during the design or fabrication processes, including a layout represented by a design file output, e.g., a GDS output.

Illustrated below are a plurality of embodiments of configurations (or layouts) including at least one main feature and at least one SRAF provided oblique to the main feature. These embodiments may be representative of configurations provided in photomasks, design data including design file output (e.g., GDS output files), and/or other representations of features useful in the design, development, and/or fabrication of devices using photolithography processes. The embodiments provided herein are not intended to be limiting in any manner and are merely exemplary in nature. The repetition of reference numerals is for ease of understanding only, and not intended to imply any connection between the configurations. The descriptions of the SRAF 110 and main feature 120 provided in reference to FIG. 1, may be applicable to any embodiment provided herein. For example, the positioning of the SRAF 110 in relation to a main feature 120, for example, may be applicable to any of the embodiments provided below.

FIG. 2 illustrates an embodiment of a configuration 200 including plurality of SRAFs 110 associated with the main feature 120; the plurality of SRAFs oblique to the main feature 120. The SRAFs 110 are “associated” with the main feature 120 in that they may contribute to imaging of the main feature 120 onto a substrate. The configuration 200 may be representative of a photomask (such as described above with reference to the photomask 100) or a design file. The SRAFs 110 are offset a distance in the horizontal direction of Ax, Bx, and Cx respectively and in the vertical direction of Ay, By, and Cy respectively. Though three SRAFs 110 are illustrated, any plurality of SRAFs may be associated with the main feature 120 and lie in oblique direction 210, for example, one or more of the center points of the SRAFs 110 may be located on the oblique direction 210. In an embodiment, the offset distance between the main feature 120 and the SRAF 110 (e.g., Ax, Bx, Cx, Ay, By, Cy) is between approximately 0.9 and 2.1 times the resolution limit of the fabrication process generation.

Referring now to FIG. 3, a configuration 300 is illustrated including the main feature 120 and four SRAFs 110 associated with the main feature 120. Each of the four SRAFs 110 is oblique to the main feature 120, for example, the center point of each of the four SRAFs 110 may lie within an area adjacent a corner of the main feature 120 (e.g., the area 150 described above with reference to FIG. 1.)

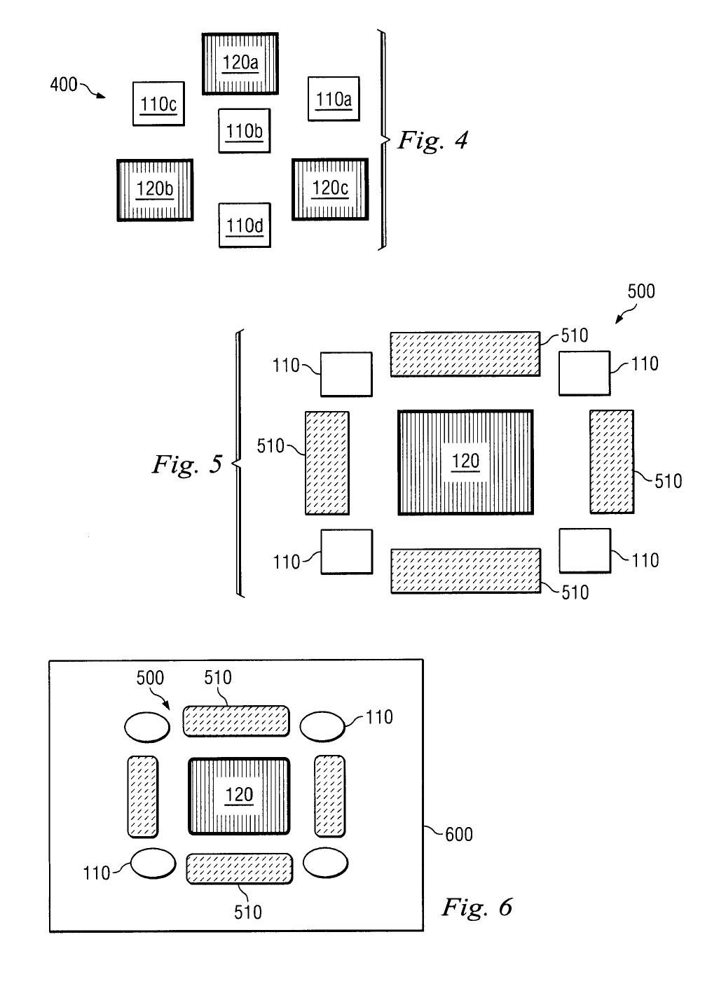

Referring now to FIG. 4, a configuration 400 is illustrated including a plurality of main features 120a, 120b, 120c and a plurality of SRAFs 110a, 110b, 110c, 110d. The main features 120a, 120b, 120c may be substantially similar to the main feature 120 described above with reference to FIG. 1. The SRAFs 110a, 110b, 110c, 110d may be substantially similar to the SRAF 110 also described above with reference to FIG. 1. The configuration 400 illustrates that a single SRAF may be associated with a plurality of main features. For example, the SRAF 110b may be associated with the main features 120a, 120b and 120c. The SRAF 110d may be associated with the main feature 120b and 120c. The configuration 400 also illustrates an embodiment where a SRAF may be oblique to a plurality of main features with which it is associated; for example, the SRAF 110d is oblique to the main features 120b and 120c. The configuration 400 also illustrates an embodiment where a SRAF may be oblique to one main feature and, although associated with a second main feature, not be oblique to the second main feature. For example, SRAF 110b is oblique to main features 120b and 120c, but is in line (e.g., parallel) with the main feature 120a.

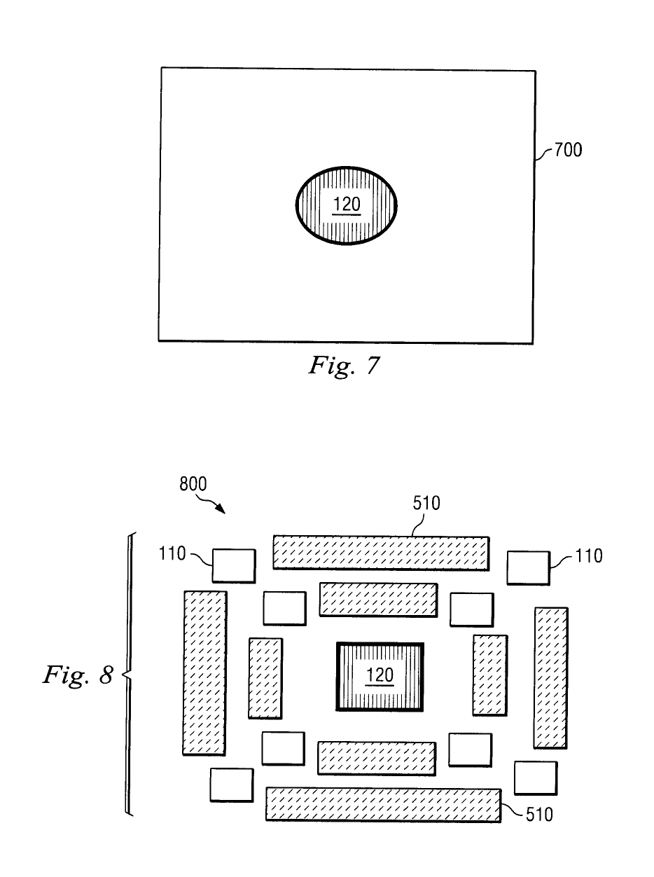

Referring now to FIGS. 5, 6, and 7, a configuration 500 is illustrated including the main feature 120, plurality of SRAFs 110, and plurality of scattering bars 510. The each of plurality of SRAFs 110 are positioned oblique the main feature 120. In particular, the SRAFs 110 are positioned oblique to a corner of the main feature 120. In contrast, the scattering bars 510 are positioned in line with the main feature 120. FIG. 5 illustrates a design file output (e.g., GDS output) including the configuration 500. FIG. 6 illustrates the configuration 500 as fabricated on a photomask 600. The photomask 600 may be substantially similar to the photomask 100 described above with reference to FIG. 1. The process limitations in fabricating the photomask 600 may result in rounded corners of the main feature 120, scattering bars 510, and SRAFs 110 as compared to the design file of FIG. 5. However, as illustrated by FIG. 6, the SRAFs 110 remain oblique to the main feature 120 (e.g., to a corner of the main feature 120) when formed on the photomask 600. The photomask 600 also illustrates that although the SRAFs 110 are formed as rectangular in the design file (e.g., GDS), when fabricated on the photomask 600 are rounded (e.g., appear as a hole). FIG. 7 illustrates the configuration 500 as formed on a portion of a wafer 700, for example, by a photolithography process utilizing the photomask 600. The main feature 120 includes a symmetric contact (e.g., via) when formed on the wafer 700. Numerous other embodiments may be provided forming a variety of other features known in the art. The SRAFs 110 and scattering bars 510, being sub-resolution, are not imaged onto the wafer 700. The radiation beam used to image features onto a substrate may be ultraviolet and/or can be extended to include other radiation beams such as ion beam, x-ray, extreme ultraviolet, deep ultraviolet, and other proper radiation energy. The wafer 700 may include silicon in a crystalline structure. In alternative embodiments, the wafer 700 may include other elementary semiconductors such as germanium, or includes a compound semiconductor such as, silicon carbide, gallium arsenide, indium arsenide, and indium phosphide.

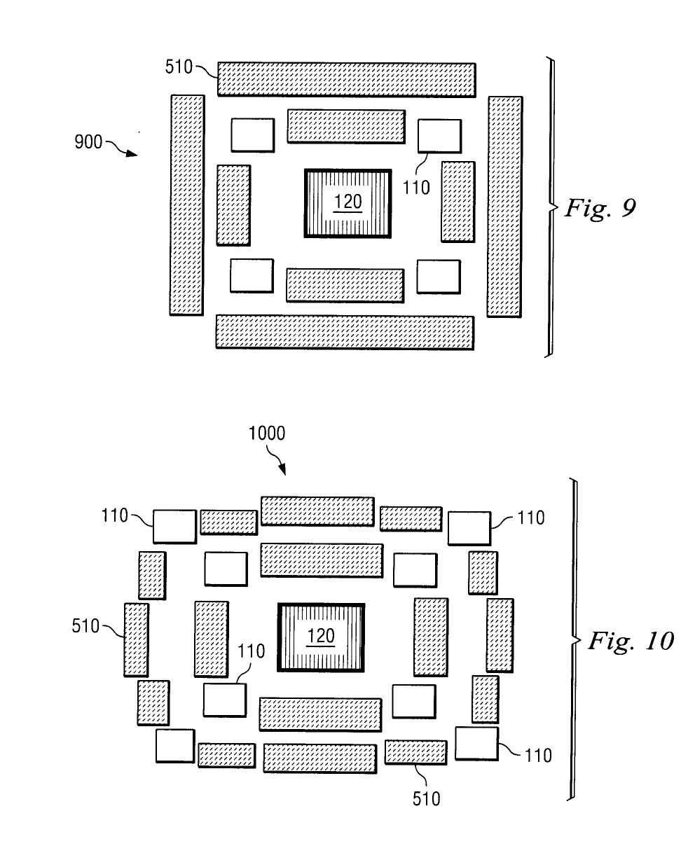

Referring now to FIGS. 8, 9, and 10, a plurality of embodiments of isolation configurations 800, 900, and 1000 including the main feature 120 are provided. Configurations 800, 900, and 1000 each include a plurality of scattering bars 510 in line with the main feature 120 and a plurality of SRAFs 110 each oblique to the main feature 120. The configurations provide embodiments providing substantially full isolation of the main features 120. One or more of the configurations 800, 900, and/or 1000 may be present in design data or formed on a photomask.

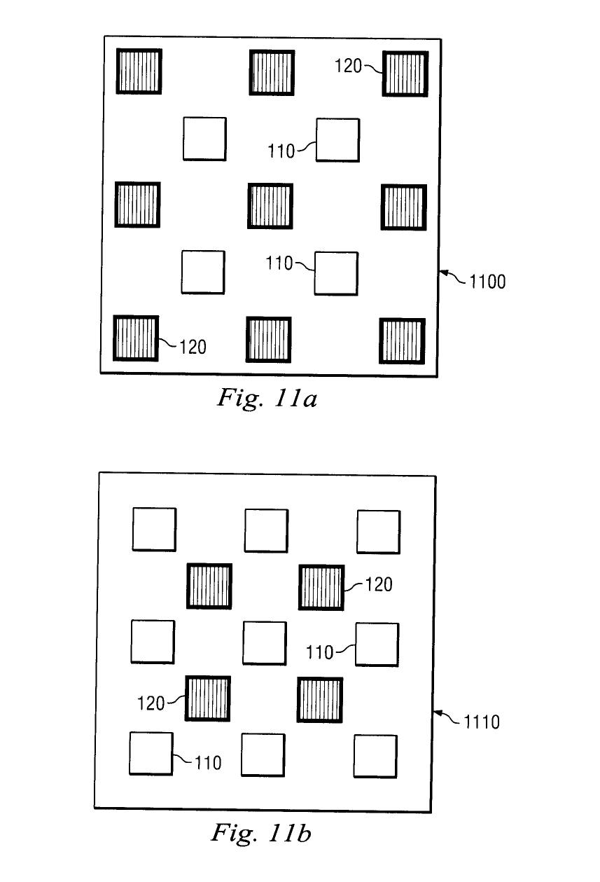

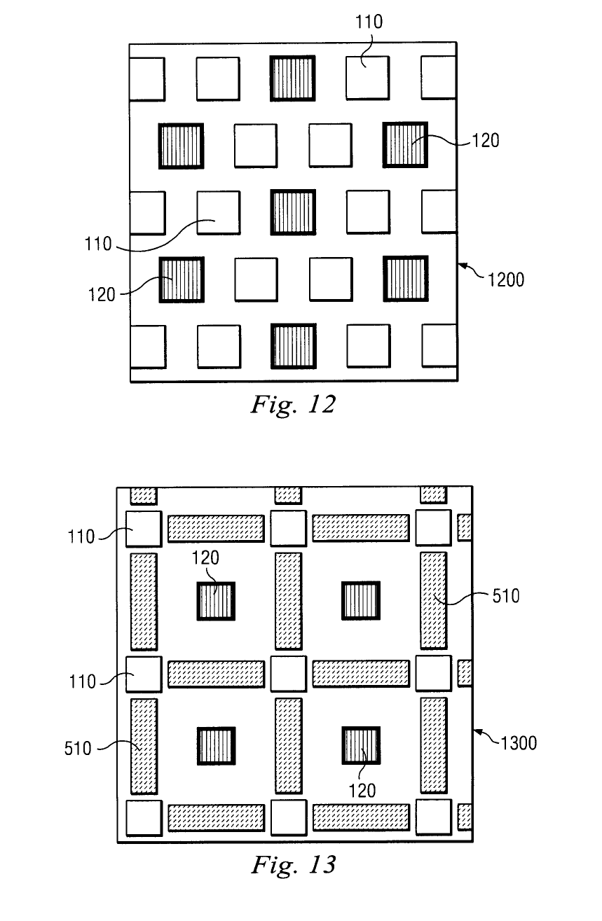

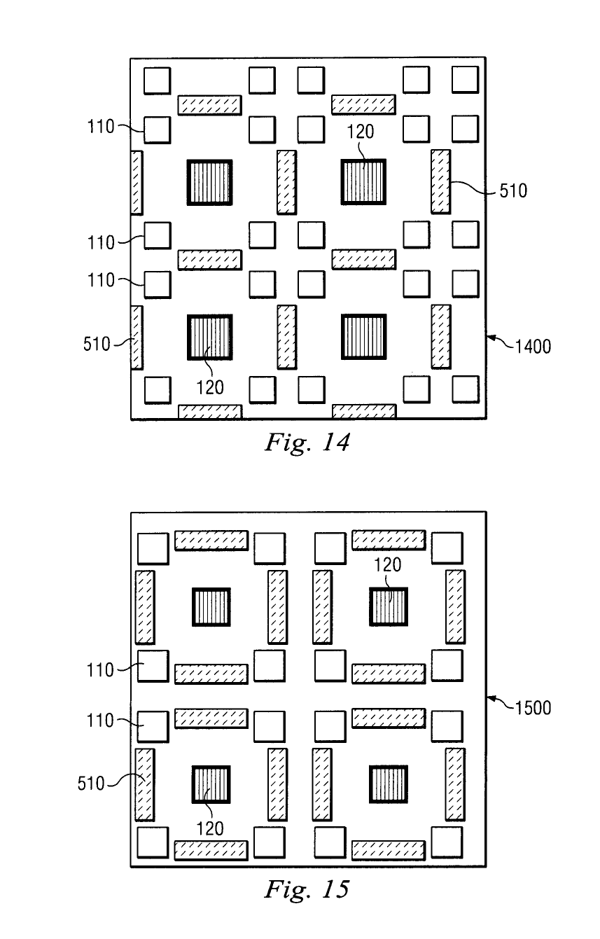

Referring now to FIGS. 11a, 11b, 12, 13, and 14, configurations 1100, 1110, 1200, 1300, 1400, and 1500 are illustrated. The configurations 1100, 1110, 1200, 1300, 1400, and 1500 are provided for illustrative purposes and not intended to be limiting in any manner. Each of the configurations 1100, 1110, 1200, 1300, 1400, and 1500 include a plurality of main features 120 and SRAFs 110. In each embodiment, at least one SRAF 110 is oblique to at least one main feature 120. The configurations 1100, 1110, 1200, 1300, 1400, and 1500 illustrate the main pattern feature 120 in a substantially regular and uniform array (e.g., a substantially uniform pitch or spacing).

Configurations 1100 and 1110 illustrate that for a small pitch of the main features 120, oblique SRAFs 110 are utilized at the vacant spaces between corners of the main features 120. In an embodiment, the pattern density of an array of main features, such as illustrated by the main features 120 in configuration 1100, is approximately 11% without oblique SRAFs 110 present. The pattern density with the addition of the oblique SRAFs 110 (e.g., the configuration 1100 as illustrated) may be approximately 21%. Configuration 1200 illustrates a small pitch of main features including a plurality of SRAFs 110, each SRAF 110 positioned oblique at least main feature 120. The oblique SRAFs 110 illustrated in configuration 1200 include a center point within an area defined adjacent the corner of the main features 120 (e.g., the area 150 described above), but without center points lying substantially on a line extending 45 degrees from a corner of the main feature 120. Configurations 1300 and 1400 illustrate a larger pitch between the main features 120 and include the use of scattering bars 510 in conjunction with the SRAFs 110. The scattering bars 510 and/or the SRAFs 110 provide for optical proximity correction and/or improvements in uniformity of density. The SRAFs 110 are positioned oblique to the main features 120 including between the corners of adjacent main features 120. Configuration 1300 illustrates a semi-dense array. Configuration 1400 illustrates a semi-isolated configuration (e.g., the main feature 120 is partially isolated by resolution enhancement technique structures). Configuration 1500 illustrates an isolated configuration.

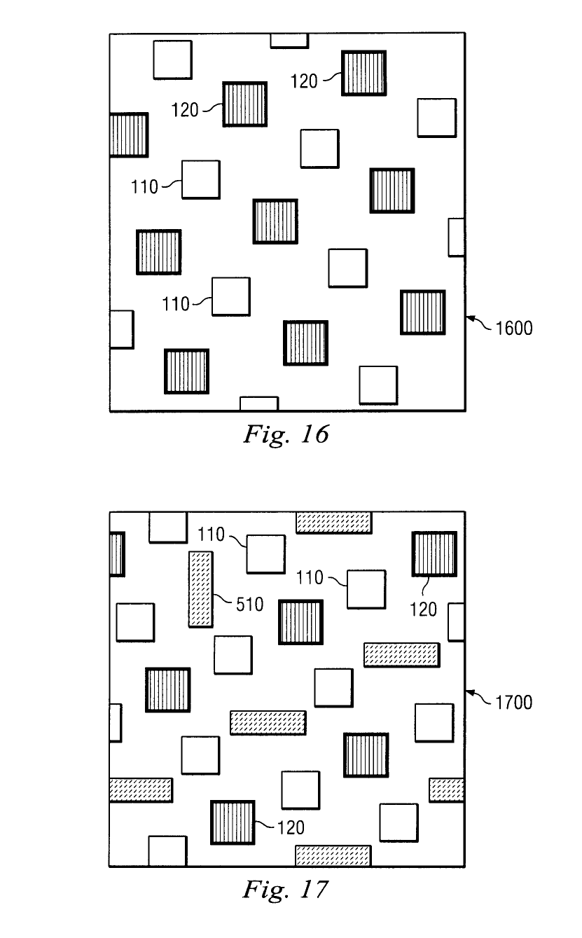

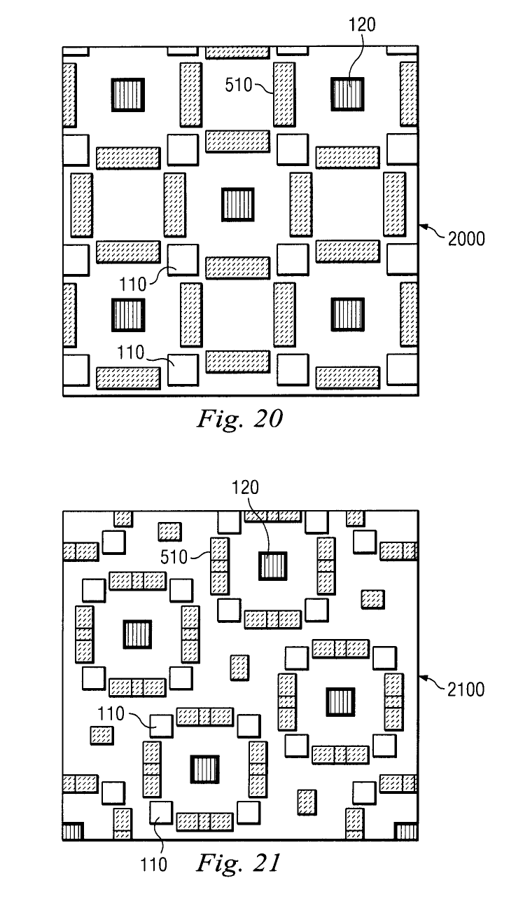

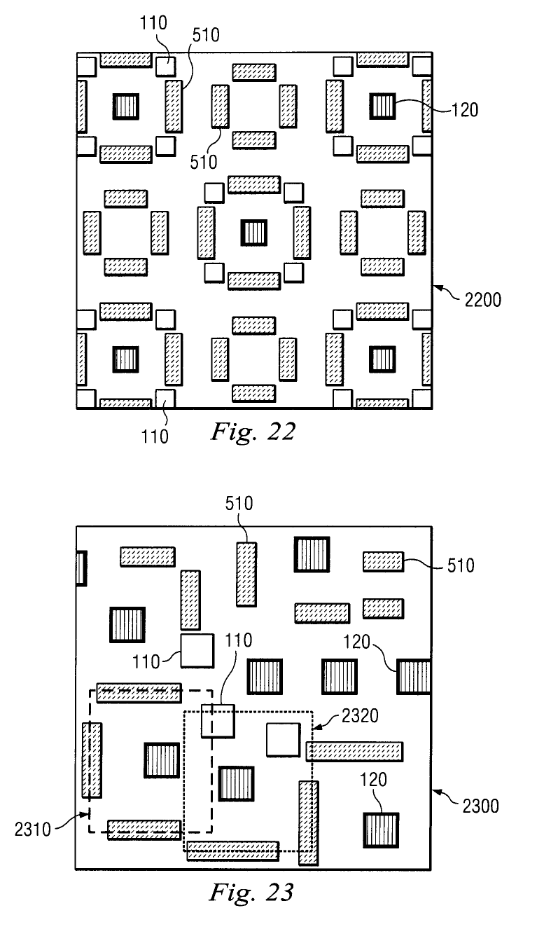

Referring now to FIGS. 16, 17, 18, 19, 20, 21, and 22, configurations 1600, 1700, 1800, 1900, 2000, 2100, and 2200 are illustrated. The configurations 1600, 1700, 1800, 1900, 2000, 2100, and 2200 are provided for illustrative purposes and not intended to be limiting in any manner. Each of the configurations 1600, 1700, 1800, 1900, 2000, 2100, and 2200 include a plurality of main features 120 and SRAFs 110. In each embodiment, at least one SRAF 110 is oblique to at least one main feature 120. The configurations 1600, 1700, 1800, 1900, 2000, 2100, and 2200 illustrate the main pattern feature 120 in a substantially non-regular and uniform array (e.g., uniform pitch or spacing).

Configuration 1600 illustrates that for a small pitch of main features, oblique SRAFs 110 are utilized at the vacant spaces between corners of the main features 120. In an embodiment of the configuration 1600, the pitch of the main features 120 is such that other RET features, such as the scattering bars 510, cannot fit between the main features 120. In an embodiment, the pattern density of an array of main features such as illustrated by the main features 120 in configuration 1600 is approximately 11% without oblique SRAFs 110. In contrast, the pattern density with the addition of the oblique SRAFs 110 (e.g., the configuration 1600) may be approximately 21%.

Configurations 1700, 1800, 1900, 2000, 2100, and 2200 illustrate relative larger pitches between the main features 120 and therefore include the use of scattering bars 510 in conjunction with the SRAFs 110. The scattering bars 510 and/or the SRAFs 110 provide for optical proximity correction and/or improvements in uniformity of density. Configurations 1900 and 2000 may be referred to as providing partial isolation of the main features 120. Configuration 2100 and 2200 may be referred to as providing substantial isolation of the main features 120. Configurations 1700 and 1800 have a density of main features 120 such that scattering bars 510 may be disposed within the array, however, isolation is not or can not be provided.

It is also noted that the configuration 1700 and 1800 while providing a SRAF 110 oblique to the main feature 120, do not provide for the center point of the SRAF 110 to lie on at a substantially 45 degree angle line as drawn from the corner of the main feature (e.g., line 160 embodiment illustrated in FIG. 1). However, the SRAFs 110 are oblique in that their center point lies within an area adjacent the main feature 120 defined by a pair of imaginary lines each traversing an edge point of the main feature (e.g., the area 150 described above with reference to FIG. 1). The isolated configurations 1900, 2000, 2100, and 2200 illustrate embodiments of a center point of the SRAF 110 located on an imaginary line extending approximately 45-degrees from the corner such as depicted by the illustrated embodiment of the line 160 of FIG. 1.

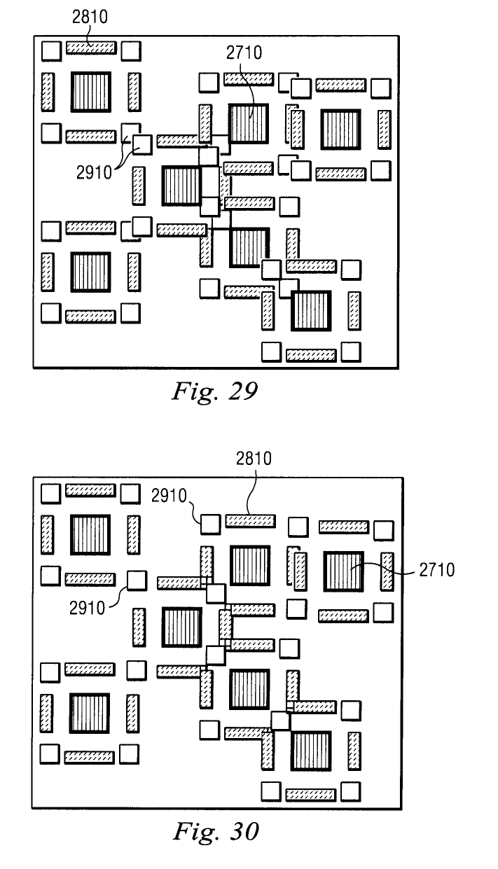

Referring now to FIG. 23, illustrated is a configuration 2300 including a configuration of main features 120 that is neither regular nor uniform. The configuration 2300 is provided for illustrative purposes and not intended to be limiting in any manner. The configuration 2300 includes a plurality of main features 120, SRAFs 110, and scattering bars 510. In other embodiments, the scattering bars 510 are omitted. Configuration 2300 includes at least one SRAF 110 that is oblique to at least one main feature 120. Referenced area 2310 illustrates one of the plurality of main features 120, three scattering bars 510 associated with the main feature 120, and one oblique SRAF 110 associated with the main feature 120. Referenced area 2320 illustrates a second of the plurality of main features 120, two scattering bars 510, and two SRAFs 110 associated and oblique to the second main feature. To optimize the performance of the SRAF 110s any variation of location of SRAFs 110 oblique to at least one main feature 120 may be provided. FIG. 29 illustrates the placement of oblique SRAFs 2910 among the main features 2710 and the scattering bars 2810. The SRAFs 2910 may be substantially similar to the SRAFs 110 described above with reference to FIG. 1 as well as numerous other embodiments detailed herein.

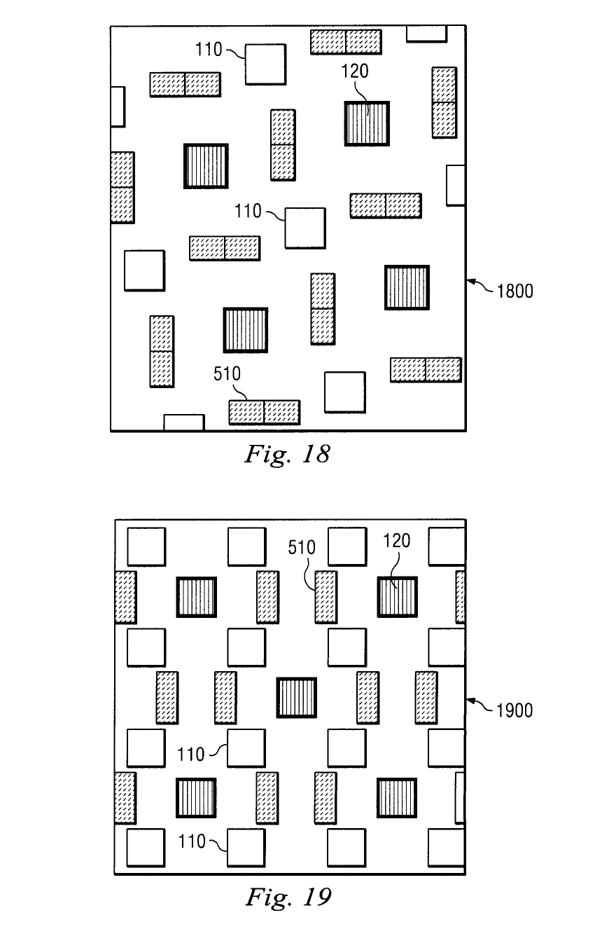

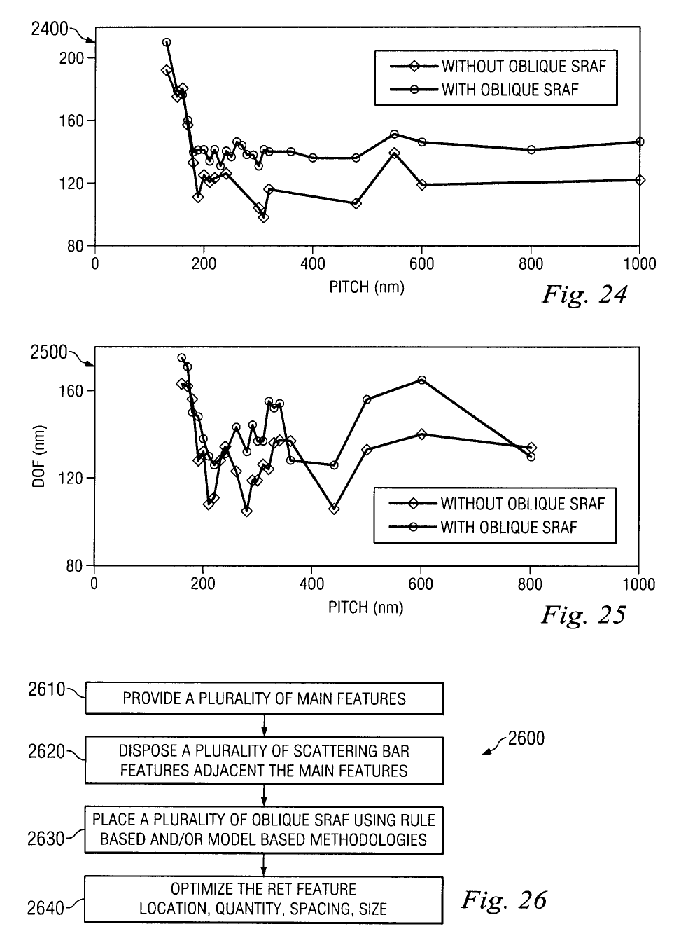

Referring now to FIGS. 24 and 25 illustrate graphs 2400 and 2500 providing for a depth of focus (DOF) at various pitches of a main feature such as, the main feature 120, in a design layout. The graphs 2400 and 2500 illustrate an improvement in DOF for a given pitch when providing oblique SRAFs in the design. The graph 2400 corresponds to results obtained from the configuration 1100b, described above with reference to FIG. 11. The graph 2500 illustrates results obtained from the configuration 1800, described above with reference to FIG. 18.

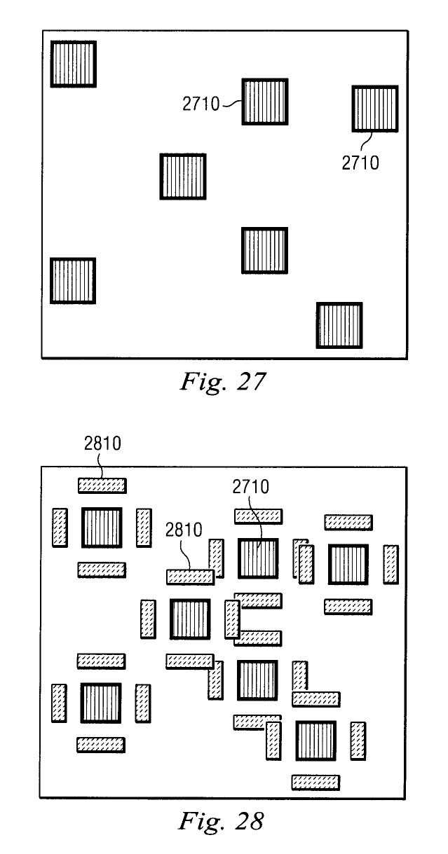

Referring now to FIGS. 26, 27, 28, 29, 30, 31, and 32 illustrated is a method 2600 of providing resolution enhancement techniques including sub-resolution assist features positioned oblique a main feature (e.g., oblique SRAFs). The method 2600 begins at step 2610 where a plurality of main features is provided. In an embodiment, the main features include an array. FIG. 27 illustrates a design file (e.g., a GDS output) including main features 2710. The main features 2710 may be substantially similar to the main features 120 described above with reference to FIG. 1. The method 2600 then proceeds to step 2620 where scattering bar features are placed adjacent and in line with the main features. In an embodiment, the scattering bar features may be selected and/or placed using a rule-based methodology. FIG. 28 illustrates the placement of scattering bar features 2810 adjacent the main features 2710. The scattering bar features 2810 may be substantially similar to the scattering bars 510 described above with reference to FIG. 5.

The method 2600 then proceeds to step 2630 where a plurality of oblique SRAFs are included in the design file. The oblique SRAFs shape, size, position, and/or quantity may be determined using rule based and/or model based methodologies. In an embodiment, the shape of the oblique SRAF (e.g., rectangular) may be rule based determination. In an embodiment, the size and location of the oblique SRAFs may be model-based determinations. The model-based determinations may take into account printing limitations (e.g., mask feature fabrication limitations), such as, threshold offsets. In an alternative embodiment, all parameters of the oblique SRAFs including shape, size, and position may be rule-based determinations. In an embodiment, the rule-based determinations may include a requirement the oblique SRAF be symmetrical. FIG. 29 illustrates the inclusion of oblique SRAFs 2910 in the layout.

The method 2600 then proceeds to step 2640 where the RET features including oblique SRAFs and scattering bars, are optimized. The parameters that may be optimized include position, shape, quantity, size, spacing, and/or various other parameters. The parameters provide for optimizing an arrangement of the layout between RET features including oblique SRAFs and scattering bars and/or main features.

Modifications that may be performed are discussed herein as exemplary only and not intended to be limiting. By way of example, one or more oblique SRAFs may be combined to form a single SRAF. In an embodiment, one or more oblique SRAFs associated with different main features may be combined to a single oblique SRAF associated with (e.g., shared by) a plurality of main features. For example, if the space between two adjacent oblique SRAFs is under a threshold, the adjacent SRAFs will merge into one SRAF. One or more of the scattering bars may be similarly combined into a single RET feature. FIG. 30 illustrates the modification of SRAFs 2910 providing for merging of two SRAFs into a single feature.

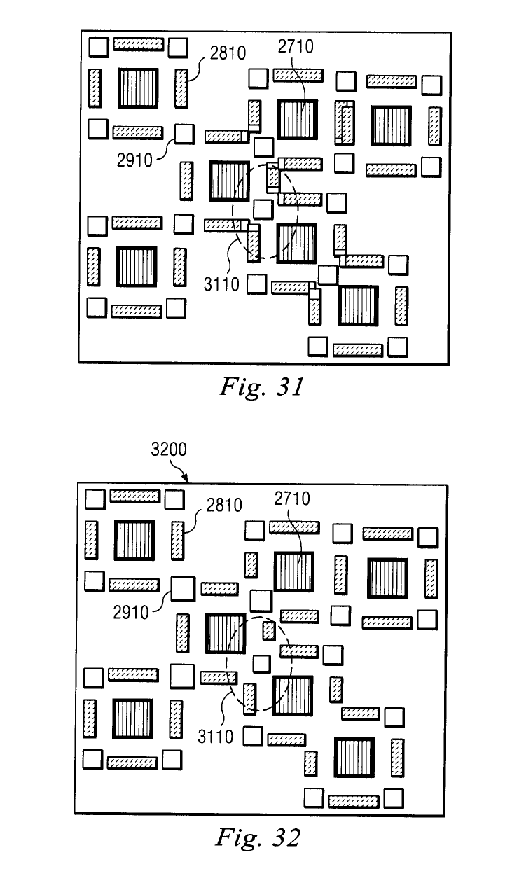

In an embodiment, the position of the oblique SRAF is changed, for example, to provide for a minimum distance between RET features and/or main features of the layout. For example, if the space between a SRAF and a main feature is insufficient, the SRAF will shift to provide a safe range of distance. In an embodiment, a RET feature, including a scattering bar, shape may be changed such that adequate spacing is provided between RET features and/or a main feature. FIG. 31 illustrates a modification of RET feature placement, shape, and/or dimensions. For example, in reference area 3110 illustrated is a modification of scattering bars 2810 to provide spacing between a scattering bar 2810 and oblique SRAF 2910.

In an embodiment, a size of a RET feature may be changed to provide proper spacing between RET features and/or main features of the layout. For example, if there is no safe range of distance for which the SRAF may shift from the main feature, the SRAF may reduce in size to keep the safe distance. Though reducing in size, the SRAF may maintain its oblique position to the main feature. The modification performed may be determined exclusively by rule-based methodologies, by model-based methodologies, or a combination thereof. FIG. 32 illustrates a modification in the size of a SRAF 2910 in reference area 3110 to provide for specified space between RET features and/or RET features and main feature 2710.

Therefore provided is a sub-resolution assist feature positioned oblique to a main feature (e.g., an oblique SRAF). The sub-resolution assist feature may be provided using rule-based and model-based methodologies. The SRAF provides for benefits of an increased window of performance for process parameters, in particular with a strong off axis illumination. An oblique SRAF is capable of being positioned between densely patterned main features. This may be useful, for example, in providing RET for SRAM (e.g., pitch of conductive lines) and random logic layouts. The SRAFs may also be generated using rule based methodologies or using rule-based in conjunction with model-based methodologies for determining shape, size, position, quantity, and/or other possible parameters. This provides benefits, for example, of a shorter generating time, symmetric shape, and an ease of mask making from simplified shape as opposed to a model-determined shape.

Although only a few exemplary embodiments of this invention have been described in detail above, those skilled in the art will readily appreciate that many modifications are possible in the exemplary embodiments without material departing from the novel teachings and advantages of this disclosure.

Thus, the present disclosure provides a photomask including a main feature and a sub-resolution assist feature (SRAF). The main feature includes a first edge and a second edge. A first imaginary line extends tangential with the first edge and a second imaginary line extends tangential with the second edge. The lines define an area adjacent the main feature and are substantially perpendicular. The SRAF is associated with the main feature. A center point of the SRAF is located in the defined area.

Also provided a layout of a photomask. The layout includes a plurality of main features. The main features may be formed in an array. A first and a second main feature of the plurality of main features are positioned such that a space is provided between a corner of the first and a corner of the second main feature. A symmetrical sub-resolution assist feature (SRAF) located in the space. The layout of the photomask may be represented by a design file output (e.g., GDS output).

Also provided is a method that provides for RET. A main feature is provided. The main feature corresponds to an integrated circuit feature. Rule-based methodology is used to determine a shape of a sub-resolution assist feature (SRAF) associated with the main feature. The SRAF is positioned adjacent the main feature. The SRAF is oblique to the main feature. A parameter of the SRAF is modified after the placement.

What is claimed is:

1. A photomask, comprising:
a main feature including a first edge and a second edge, wherein a first imaginary line tangential with the first edge and a second imaginary line tangential with the second edge define an area adjacent the main feature, wherein the first imaginary line and the second imaginary line are substantially perpendicular; and
a sub-resolution assist feature (SRAF) associated with the main feature, wherein a center point of the SRAF is located in the defined area.

2. The mask of claim 1, wherein the first edge is defined by a point on the main feature that is furthest, in a first direction, from a center point of the main feature.

3. The mask of claim 2, wherein the second edge is defined by a point on the main feature that is furthest, in a second direction, from a center point of the main feature, the second direction being opposite the first direction.

4. The mask of claim 1, wherein the entire SRAF lies in the defined area.

5. The mask of claim 1, wherein the SRAF is symmetrical.

6. The mask of claim 1, wherein the SRAF is rectangular.

7. The mask of claim 1, wherein the first edge and the second edge form a corner of the main feature, and wherein the center point of the SRAF lies on a third imaginary line extending from the corner at an approximately 45-degree angle.

8. The mask of claim 1, wherein the main feature provides a pattern for a contact of an integrated circuit device.

9. The mask of claim 1, further comprising:
a scattering bar associated with the main feature, wherein the scattering bar is positioned in line with the main feature.

10. A layout of a photomask, comprising:
a plurality of main features, wherein a first and a second main feature of the plurality of main features are positioned such that a space is provided between a corner of the first and a corner of the second main feature; and
a sub-resolution assist feature (SRAF) located in the space, wherein the SRAF includes a symmetrical shape.

11. The device of claim 10, wherein the SRAF is oblique to the corner of the first main feature.

12. The mask of claim 10, further comprising:
a plurality of scattering bars positioned adjacent and in line each side of the first main feature and the second main feature.

13. The mask of claim 10, wherein the plurality of main features form an array.

14. A method, comprising:
providing a main feature, wherein the main feature corresponds to an integrated circuit feature;
using a rule-based methodology to determine a shape of a sub-resolution assist feature (SRAF) associated with the main feature;
placing the SRAF having the determined shape adjacent the main feature, wherein the SRAF is oblique to the main feature;
modifying a parameter of the SRAF after the placement.

15. The method of claim 14, wherein the modifying the parameter of the SRAF includes a model-based methodology.

16. The method of claim 14, wherein the modifying the parameter includes modifying a size of the SRAF.

17. The method of claim 14, further comprising:
placing a scattering bar adjacent the main feature and the SRAF.

18. The method of claim 14, wherein providing the main feature includes providing an array of features corresponding to integrated circuit features.

19. The method of claim 14, wherein the shape of the SRAF is symmetrical.

20. The method of claim 14, wherein the modifying the parameter includes modifying a distance between the SRAF and the main feature, and wherein the distance is determined by at least one of a rule-based methodology and a model-based methodology.
